(19) United States
(12) Patent Application Publication
(10) Pub. No.: US 2014/0290052 A1
(43) Pub. Date: Oct. 2, 2014

(54) Apparatus For Coupling Circuit Boards

(71) Applicant: Control Techniques Limited, Newtown (GB)

(72) Inventors: Dnyaneshwar Prabhakarrao Bujade, Newtown (GB); Sarang Sharad GHODKE, Newtown (GB); Dilesh Arvind Raut, Pune (IN)

(73) Assignee: Control Techniques Limited, Newtown (GB)

(21) Appl. No.: 14/228,964

(22) Filed: Mar. 28, 2014

(30) Foreign Application Priority Data
Mar. 28, 2013 (IN) 1206/MUM/2013

(51) Int. Cl. H05K 13/00

(52) U.S. Cl. CPC H05K 13/0023
USPC 29/830; 29/729

(57) ABSTRACT

An apparatus for connecting two or more circuit boards, the apparatus comprising: a first circuit board comprising a first surface and a second surface, the second surface having a first conductive pad; a second circuit board comprising a third surface and a fourth surface, the third surface having a second conductive pad; a fixing means configured to engage with the first circuit board and the second circuit board to couple the first circuit board to the second circuit board, wherein, when coupled, the fixing means is electrically isolated from one of the first circuit board and the second circuit board; and an electrically conductive spacer configured to electrically couple the first conductive pad and the second conductive pad.

### CROSS-REFERENCE TO RELATED APPLICATION

This application claims the benefit and priority of Indian Patent Application No. 1206/MUM/2013 filed Mar. 28, 2013. The entire disclosure of the above application is incorporated herein by reference.

### FIELD

This invention relates to an apparatus for coupling a plurality of circuit boards. It is particularly suitable for an apparatus for electrically coupling two or more printed circuit boards (PCBs).

### BACKGROUND

In electrical devices it is common to use circuit boards to connect the electrical components of the device. As the number of components increases with the complexity of the device, multiple circuit boards may be used. The multiple circuit boards may be arranged in a stacked or layered fashion such that the space within the electrical device is optimised. In order to couple the multiple circuit boards together, various methods may be employed. One method is to use a combination of a screw and hollow conductor. If electrical coupling is desired, plated through holes (PTHs) in the circuit boards, conductive pads/conductive washers and metal screw inserts allow an electrical connection between the screw, hollow conductors (typically copper or brass pillars) and the circuit boards such that a current is able to flow between the multiple circuit boards.

During the assembly process of the electrical device, there exists the possibility of errors. In particular, the hollow conductors are often manually inserted and therefore one or more of the hollow pillars may be omitted and absent from the electrical device. In this case, given the fact that the screw is also electrically conductive and forms an electrical path with the PTHs and pads, an electrical path is still established between the circuit boards.

Although the metal screw is an electrical conductor, the resistivity of the screw is high compared to that of a hollow conductor. Furthermore, the ridged thread on the screw is such that a perfect contact with the plated through holes and any screw insert is not achieved, and as a result an electrical connection between the thread of the screw shaft and the plated through holes and screw insert is only made at a few contact points on the thread. This drastically reduces the current capacity of the screw, and, given the screw's high resistivity, hot spots are created when high current flows through the screw at the contact points. As the screw heats up, the contact area between the screw and the plated through hole can reduce further as a result of the uneven expansion of metals. Further, carbon deposition may occur which increases the resistance of the electrical connection between the screw and the plated through hole. This in turn increases the voltage drop across the screw and leads to the additional generation of heat. The reliability and safety of the electrical device is therefore compromised and there is an increased risk of fire inside the electrical device. Furthermore, the heating up of the screw may lead to a heating up of the gas surrounding the screw and the undesired effects of arcing, whereby a current is able to flow through an insulator, is increased.

An alternate arrangement for connecting more than one circuit board is a flexilink such as that provided by Electronic Precision Technology. A flexilink comprises a plurality of metal pillars housed in an insulating casing. The plurality of pillars is shaped such the pillars can be inserted into standard pitch holes of printed circuit boards. However, flexilinks are provided in set sizes and shapes and as such their versatility and current carrying capacity is limited due to their high resistance. Furthermore, flexilinks must be soldered to the circuit board.

A further arrangement for connecting multiple circuit boards is by passing conductive studs through the circuit boards and soldering the studs at locations appropriate for the circuit in question. Again this is limited in terms of flexibility and current carrying capacity, and is further limited in that the strength of the connection between circuit boards is low.

It is therefore desirable to provide an apparatus that overcomes the aforementioned problems.

### SUMMARY

According to a first aspect there is provided an apparatus for connecting two or more circuit boards as defined in claim 1 of the appended claims. Thus there is provided a first circuit board with a first surface and a second surface. The second surface has a first conductive pad located thereon. There is also provided a second circuit board with a third surface and a fourth surface. The third surface has a second conductive pad located thereon. A fixing means is configured to engage with the first circuit board and the second circuit board to couple the first circuit board to the second circuit board, wherein, when coupled, the fixing means is electrically isolated from one of the first circuit board and the second circuit board. The apparatus also comprises an electrically conductive spacer configured to electrically couple the first conductive pad and the second conductive pad.

By having a fixing means that is electrically isolated from one of the first circuit board and the second circuit board, in the event that the electrically conductive spacer is not present subsequent to assembly of the circuit board, there will be no electrical connection provided by the fixing means between the first circuit board and the second circuit board. As a result of this, undesired effects of overheating of the fixing means and potential arcing of current are avoided.

Preferable and optional features are defined in the dependent claims.

Optionally, the first circuit board comprises a first hole extending between the first surface and the second surface, and the second circuit board comprises a second hole extending between the third surface and the fourth surface. Further optionally the first conductive pad is located proximate to the first hole and the second conductive pad is located proximate to the second hole.

Optionally, the fixing means is configured to engage with the first hole and the second hole. Further optionally the electrically conductive spacer is configured to allow insertion of the fixing means therethrough, and the fixing means is electrically isolated from the electrically conductive spacer.

Optionally, at least one of the first circuit board and the second circuit board comprises a printed circuit board (PCB).

Optionally, the electrically conductive spacer is substantially cylindrical in shape and is made of brass.

Optionally, the first surface comprises a third conductive pad located proximate to the first hole, and the first surface further comprises an isolation means located to electrically isolate the third conductive pad from the fixing means.

Optionally, the fixing means is a screw with a screw head. This ensures a strong and simple connection between the two circuit boards. Further optionally, the fixing means is electrically isolated from both the first and second circuit boards such that no current is able to pass through the fixing means.

Further optionally, an isolation means is located between the head of the screw and the third conductive pad. The isolation means may comprise an insulating material.

Optionally, the fixing means is a nut and bolt.

Optionally, one or both of the nut and bolt are made of plastic.

Optionally, the fixing means is a plastic PCB holder.

Optionally, the apparatus further comprises one or more plugs configured to engage with the electrically conductive spacer.

Optionally, the fixing means is a C-shaped spring clamp or a bow shape spring clamp.

Optionally, the apparatus is arranged to be electrically connected to a detection system, and the detection system is configured to detect a signal indicative of the presence of the electrically conductive spacer. Further optionally, the detection system detects the presence of the electrically conductive spacer by monitoring a ripple voltage.

Optionally, an error message is displayed when the electrically conductive spacer is detected as not being present or when the ripple voltage exceeds a predetermined ripple voltage threshold.

According to a second aspect there is provided a method for connecting two or more PCBs as defined in claim 25 of the appended claims.

Optionally, the method comprises providing a first hole extending between the first surface and the second surface, and providing a second hole extending between the third surface and the fourth surface. Further optionally, the first conductive pad is located proximate to the first hole and the second conductive pad is located proximate to the second hole. Further optionally, the fixing mean is configured to engage with the first hole and the second hole, and the electrically conductive spacer is configured to allow insertion of the fixing means therethrough.

Further optionally, the method comprises providing a detection system configured to detect a signal indicative of the presence of the electrically conductive spacer.

Optionally, the method further comprises detecting the presence of the electrically conductive spacer by monitoring a ripple voltage.

Optionally, the method further comprises displaying an error message when the electrically conductive spacer is detected as not being present.

Optionally, the method further comprises displaying an error message when the ripple voltage exceeds a predetermined voltage threshold.

With all the aspects, preferable and optional features are defined in the dependent claims.

### BRIEF DESCRIPTION OF THE DRAWINGS

Embodiments will now be described, by way of example only, and with reference to the drawings in which:

FIG. 1 illustrates a diagram of a known arrangement for connecting two circuit boards together.

FIG. 2 illustrates an arrangement according to a first embodiment for connecting two circuit boards together.

FIG. 3 illustrates an arrangement according to a second embodiment for connecting two circuit boards together.

FIG. 4 illustrates an example three phase rectifier for use with the embodiments disclosed herein.

FIG. 5 shows an example DC bus voltage waveform of a three phase power supply with all spacers/collars present.

FIG. 6 shows an example DC bus voltage waveform of a three phase power supply with one spacer/collar missing.

FIG. 7 shows an arrangement according to further embodiments for connecting two circuit boards together.

FIG. 8 shows an arrangement according to a further embodiment for connecting two circuit boards together.

FIG. 9 shows an arrangement according to still further embodiments for connecting two circuit boards together.

In the figures, like elements are indicated by like reference numerals throughout.

### DETAILED DESCRIPTION

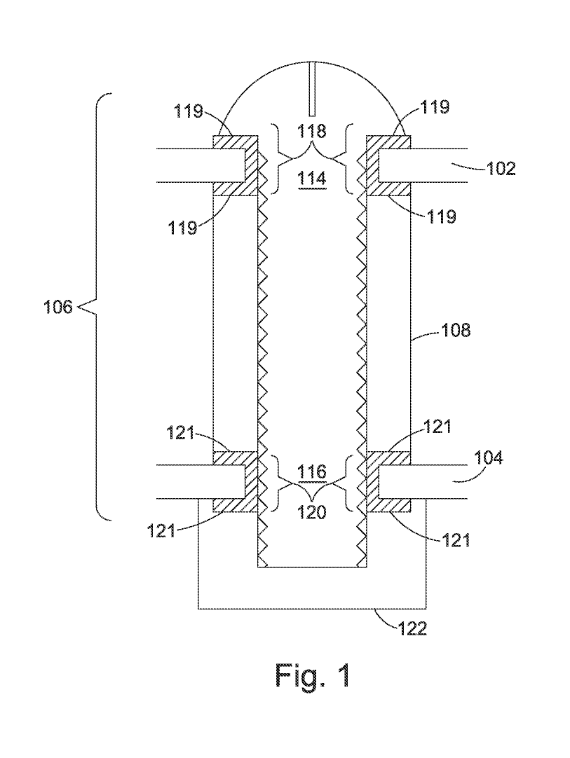

FIG. 1 shows a known apparatus for connecting two or more circuit boards together. The apparatus comprises a first circuit board 102 and a second circuit board 104 which may have electrical components soldered thereto. The plane of the first circuit board 102 is arranged parallel to and above the second circuit board 104 as a layered structure, with a space therebetween as shown in FIG. 1. The first and second circuit boards comprise a first hole 114 and second hole 116 respectively. The first and second holes align in a direction perpendicular to the plane of the first circuit board 102 and the second circuit board 104, and are shaped to allow insertion of a screw 106 through the first hole 114 and the second hole 116 to attach the first circuit board 102 to the second circuit board 104. The first hole 114 comprises a first Plated Through Hole (PTH) shown by the shaded region 118. The first PTH 118 comprises an electrically conductive material disposed around the circumference of the first hole 114, and extending over the first circuit board 102 to form electrically conductive pads 119 on both sides of the first circuit board 102, in the vicinity of the first hole 114. Accordingly, the first PTH 118 forms an electrically conductive path between both sides of the first circuit board 102, as would be understood by the person skilled in the art. The second hole 116 also comprises a second PTH, shown by the shaded region 120, comprising electrically conductive pads 121. Similarly, the second PTH 120 forms an electrically conductive path between both sides of the second circuit board 104 as would be understood by the person skilled in the art.

The screw 106, being in physical contact with both of the first PTH 118 and the second PTH 120, forms an electrical connection with the first circuit board 102 and the second circuit board 104. As a result, current is able to flow from the first circuit board 102, through the screw 106, and into the second circuit board 104 and vice versa.

A hollow spacer 108 is located between the first circuit board 102 and the second circuit board 104, as shown in FIG. 1. The spacer 108 is made of an electrically conductive material and forms a collar or pillar around the screw 106. When the apparatus is assembled, the spacer 108 physically contacts the underside of the first circuit board 102 in the vicinity of the first hole 114 thereby making an electrical connection with the conductive material, for example metal such as copper of the first PTH 118 and the electrically conductive material of the spacer 108. Similarly, the spacer 108 also physically contacts the upper side of the second circuit board 104, in the vicinity of the second hole 116 such that an electrical connection is made between the spacer 108 and the second PTH 120. In this manner, a current in the first circuit board 102 has an alternate path through the spacer 108 to reach the second circuit board 104, and vice versa.

An insert 122 is located to engage with the thread of the screw 106 to secure the screw to the apparatus of FIG. 1. The insert 122 may be provided in physical contact with the PTH 120 of the second circuit board 104 as shown in FIG. 1. The insert 122 may comprise an electrically conductive material such that an additional conductive path is formed between the PTH 120, second circuit board 104, insert 122, screw 106 and first circuit board 102.

In the prior art embodiment shown in FIG. 1, in the event that the spacer 108 is missed during assembly of the device, current is still able to travel between the first circuit board 102 and the second circuit board 104 via the screw 106, plated through holes 118 and 120, and the insert 122. When the spacer 108 is present in the assembly, the current between the first circuit board 102 and the second circuit board 104 has an alternative route through the electrically conductive spacer 108.

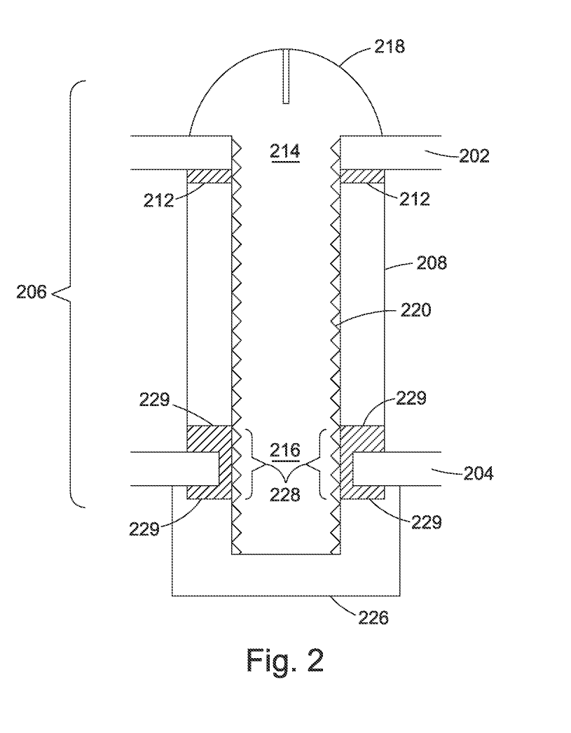

FIG. 2 shows the coupling of two circuit boards, for example two PCBs, according to a first embodiment. The arrangement of FIG. 2 comprises a first circuit board 202 and a second circuit board 204. The plane of the first circuit board 202 is arranged parallel and above the second circuit board 204 in a layered structure, with a space therebetween as shown in FIG. 2. The first and second circuit boards of FIG. 2 comprise a first hole 214 and a second hole 216 respectively. The first and second holes align in a direction perpendicular to the plane of the first circuit board 202 and the second circuit board 204, and are shaped to allow insertion of a screw 206 through the first hole 214 and the second hole 216 to couple the first circuit board 202 to the second circuit board 204. An insert 226 is located to engage with the thread of the screw 206 to secure the screw to the apparatus of FIG. 2. The insert 226 is provided in physical contact with the second circuit board 204 as shown. The insert 226 may be made of an electrically conductive material, such as brass for example.

In the embodiment of FIG. 2, the second hole 216 comprises a PTH 228, whereas the first hole 214 does not comprise a PTH. The PTH 228 comprises an electrically conductive material disposed around the circumference of the second hole 216, and extending over the second circuit board 204 to form electrically conductive pads 229 on both sides of the second circuit board 204, in the vicinity of the second hole 216, the conductive pads 229 typically comprising a ring shape. Accordingly, the PTH 228 forms an electrically conductive path between both sides of the second circuit board 204, as would be understood by the person skilled in the art. When the first circuit board 202 is mechanically coupled to the second circuit board 204 by the screw 206 and the insert 226, the shaft 220 (comprising the thread) of the screw 206, although being in physical contact with the edges of hole 214 and the PTH 228, is only electrically coupled to the second circuit board 204 due to the PTH 228 and the insert 226. Since the first hole 214 does not comprise a PTH, the shaft 220 of the screw 206 is not in contact with an electrically conductive surface on the first circuit board 202, and accordingly a current is not able to pass directly from the first circuit board 202 to the shaft 220 of the screw 206, or vice versa.

A spacer 208, formed of an electrically conductive material and configured to allow insertion of the screw shaft 220 therethrough, is located between the first circuit board 202 and the second circuit board 204. The spacer 208 may be substantially cylindrical in shape such that the screw shaft 220 is able to be inserted through the central axis of the spacer 208. The circular ends of the cylinder are able to make physical contact with both the first circuit board 202 and the second circuit board 204 by being positioned flush with the underside of the first circuit board 202 and the top side of the second circuit board 204. One or more conductive pads 212 are located on the underside of the first circuit board 202, and in the vicinity of the first hole 214 such that they surround the first hole 214 and typically comprise a ring shape and provide an electrically conductive contact on the first circuit board 202. The conductive pads 212 may be made of any suitable electrically conductive material, such as copper for example. Spacer 208 may comprise a collar.

When assembled, the spacer 208 physically contacts conductive pads 212 and 229, thereby forming an electrically conductive path between the conductive pads 212, the spacer 208 and the PTH 228. The spacer 208 need not necessarily by cylindrical in shape, and may be another shape such as a cuboid. Indeed the spacer 208 may be any shape that allows insertion of a screw 206 therethrough, and which contacts the conductive pads 212 and the conductive pads 229 of the PTH 228.

When the apparatus is assembled as shown in FIG. 2, a conductive path is therefore formed between the first circuit board 202 and the second circuit board 204 by the conductive pads 212 of the first circuit board, the spacer 208, and the conductive pads 229 of the PTH 228 of the second circuit board 204. As can be seen, if the spacer 208 is not present, the screw 206 alone does not form a conductive path between the first circuit board 202 and the second circuit board 204. The spacer 208 is able to complete the conductive path between first circuit board 202 and second circuit board 204, and the screw 206 alone without the spacer 208 cannot achieve this as the first circuit board 202 is isolated from the screw 206.

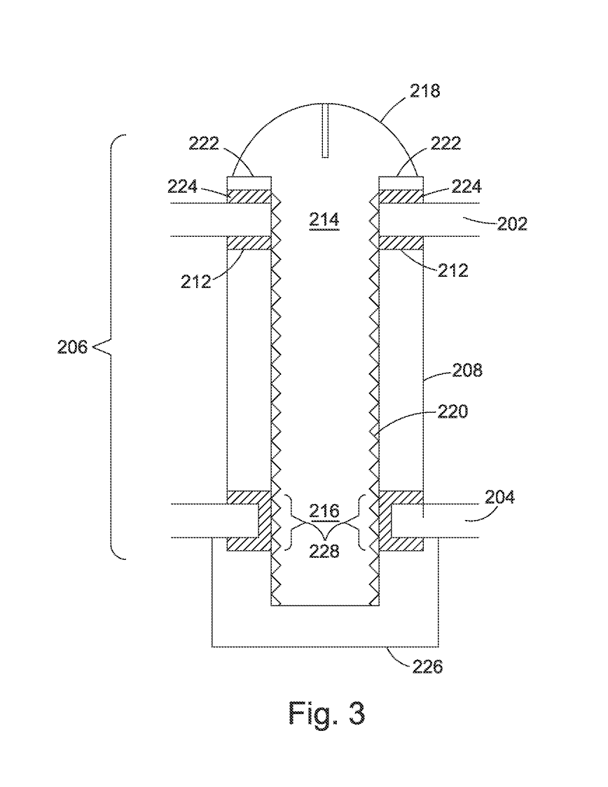

Another embodiment is shown in FIG. 3. In this embodiment, the first hole 214 does not comprise a PTH, and conductive pads 212 are located on the underside of the first circuit board 202 as previously described. Additionally, conductive pads 224 are located on an opposite side of the first circuit board 202 to the conductive pads 212, and in the vicinity of the first hole 214. The conductive pads 224 also form a ring or other shape around the first hole 214 and therefore an electrically conductive contact is provided on both sides of the first circuit board 202 due to conductive pads 212 and 224. The second hole comprises a PTH 228 as described above. In this embodiment, an isolation means 222 is located on the top side of the first circuit board 202, on top of the conductive pads 224. When the screw 206 is inserted through the hole 214 in the first circuit board 202, the isolation means 222 ensures that the head 218 of the screw 206 does not come into electrical contact with the conductive pads 224. This may be achieved, for example, if the isolation means 222 is an insulating ring formed around the shaft 220 of the screw 206 and between the head 218 and the conductive pads 224. The insulating ring may be made of any suitable material that is an electrical insulator, such as rubber or plastic for example. The isolation means 222 need not necessarily be an insulating ring, and need only be a structure that provides electrical insulation between the head 218 of the screw 206 and the conductive pads 224.

In the embodiment of FIG. 3, electrical isolation of the screw 206 from the first circuit board 202 is also achieved since the first hole 214 does not comprise a PTH. As the conductive pads 224 are present in this embodiment, any circuit board that already comprises conductive pads 224 does not need to be adapted in order to ensure electrical isolation of the screw 206 from the first circuit board 202. The conductive pads 224 may be any electrically conductive area that is present on the first circuit board 202 and located such that, in the absence of the isolation means 222, the head 218 of the screw 206 would make contact with the electrically conductive area. By electrically isolating the screw 206 from the first circuit board 202 in this manner, a greater range of circuit boards can be used since no adaptation is required to achieve the isolation.

The above embodiments may be modified such that at least one or both of the first circuit board 202 and the second circuit board 204 is electrically isolated from the screw 206 in a alternative way. For both of the embodiments of FIGS. 2 and 3, the second hole 216 need not comprise a PTH, but may instead only comprise conductive pads 229 without the metal plating of the plated through hole being present on the inside surface of the second hole 216. The conductive pads 229 may only be present on the surface of the second circuit board 204 facing the first circuit board 202, but may also be present on both sides of the second circuit board 204.

In the case that the conductive pads 229 are only present on the surface of the second circuit board 204 facing the first circuit board 202, an electrically conductive path is not formed between the second circuit board 204, the insert 226 and the screw 206. Therefore the isolation means 222 shown in FIG. 3 is not necessary. This is also the case if the first hole 214 comprises a PTH. Since the second circuit board is electrically isolated from the screw 206, the first circuit board 202 need not be.

In the case that the conductive pads 229 are present on both sides of the second circuit board 204, the isolation means 222 may still not be necessary by instead electrically isolating the second circuit board 204 from the screw 206 in the following way: first of all, in the absence of isolation means 222, the screw 206 would form an electrically conductive path with the first circuit board 202. As the second hole 216 does not comprise a PTH, isolation of the second circuit board 204 may be achieved by using an insert 226 made of an electrically insulating material, instead of metal, for example plastic. In this way the second circuit board 204 is electrically isolated from the screw 206, by the plastic insert. This is also the case if the first hole 214 comprises a PTH, since the first circuit board 202 need not be electrically isolated from the screw 206 when an insulating insert is present.

The conductive pads 212, 224 need not form a ring around the first hole 214, and may instead be areas of electrically conductive material of a different shape, located proximate to the first hole 214. Indeed any shape of conductive pad 212 is suitable as long as an electrical connection is formed between the conductive pad 212 and the spacer 208.

The embodiments described above may be extended to connect more than two circuit boards. In the case of more than two circuit boards, spacers 208 are placed between each circuit board to achieve one or more electrically conductive paths. In the absence of any spacer 208, an electrically conductive path is not achieved between the boards concerned since the screw is electrically isolated from one or both of the boards concerned by any of the features described above. For example, for three circuit boards, in the event that a spacer 208 is not present between boards two and three, no electrically conductive path is formed between those boards since there is no electrically conductive path between one or both of boards two and three and the screw 206.

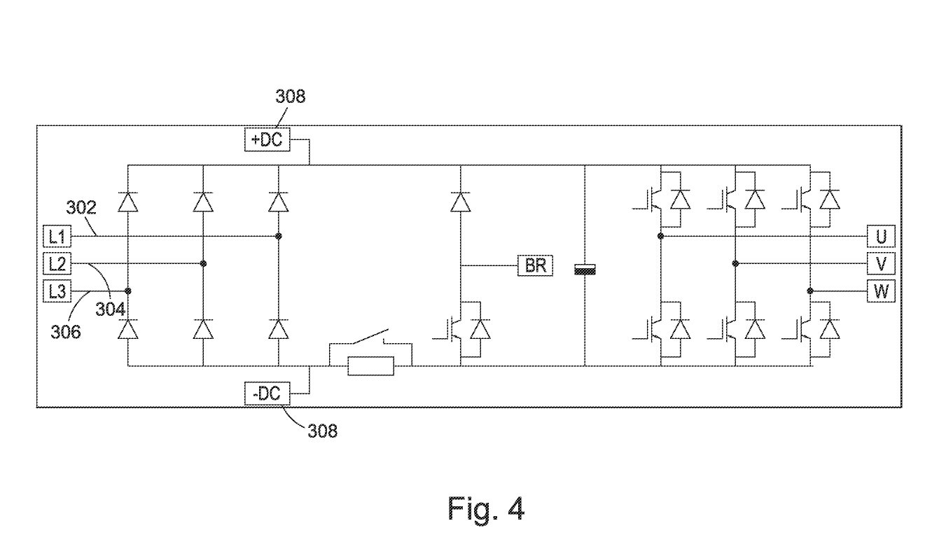

Thus an apparatus for coupling at least two circuit boards is disclosed. The electrical coupling of the circuit boards is only achieved when one or more spacers 208 are present, and therefore the electrical coupling may be used to detect the presence of a spacer 208. FIG. 4 shows an exemplary circuit for such detection. In FIG. 4, circuit board to circuit board connections such as those shown in FIG. 2 are located on connections 302, 304, and 306. The circuit board to circuit board connections may each comprise a single spacer 208 as described above, or may alternatively each comprise multiple spacers connected in series. These series-connected spacers may span two or more circuit boards. For example, the spacers may be connected in series and connect two circuit boards at two different points. If any of the series-connected multiple spacers are not present, no electrically conductive path is formed through the associated circuit board to circuit board connection.

In a three phase system, DC bus capacitors are used to filter an input ripple frequency in the DC bus. The input ripple frequency for a three phase system may be 300 Hz, for example. As would be understood by the person skilled in the art, the value of such capacitors is optimised for the frequency of the DC bus in order to bring the ripple of the DC bus down to an acceptable level and to minimise cost.

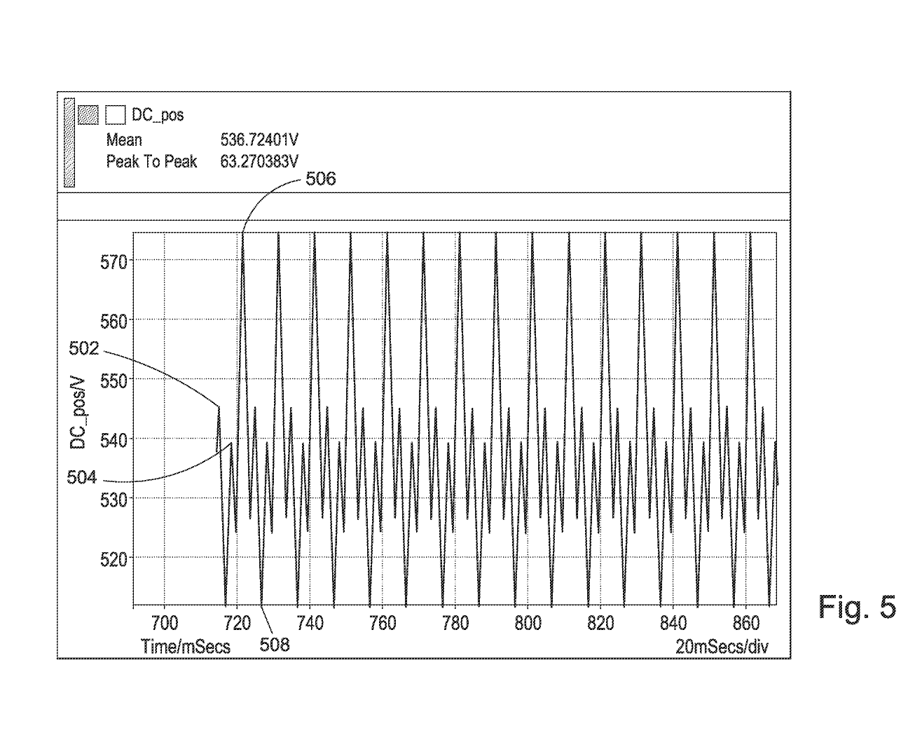

The circuit in FIG. 4 represents a three phase rectifier and L1, L2, and L3 each represent one phase of a three phase input. The ripple on a DC bus 308 is monitored by an algorithm written in software of a microprocessor (not shown), and the algorithm detects whether ripple voltage on the DC bus is within a ripple voltage threshold. In the event that, for example, one of the spacers 208 on any of circuit board to circuit board connections 302, 304, or 306 is missing, the corresponding phase line will be disconnected such that only two of three phases will reach the three phase rectifier. The missing phase is detected by the microprocessor as an increased ripple voltage in the DC bus 308 greater than the ripple voltage threshold. The microprocessor monitors for the peaks and troughs of the DC bus ripple voltage. FIG. 5 shows an example waveform of the ripple voltage across the DC bus 308 when the spacers 208 are present on all three of the circuit board to circuit board connections 302, 304 and 306. Peaks 502, 504 and 506 show the voltage for each of the three phases. The difference between peak 506 and a trough 508 shows the value of the ripple voltage, which in the example of FIG. 5 is 63V.

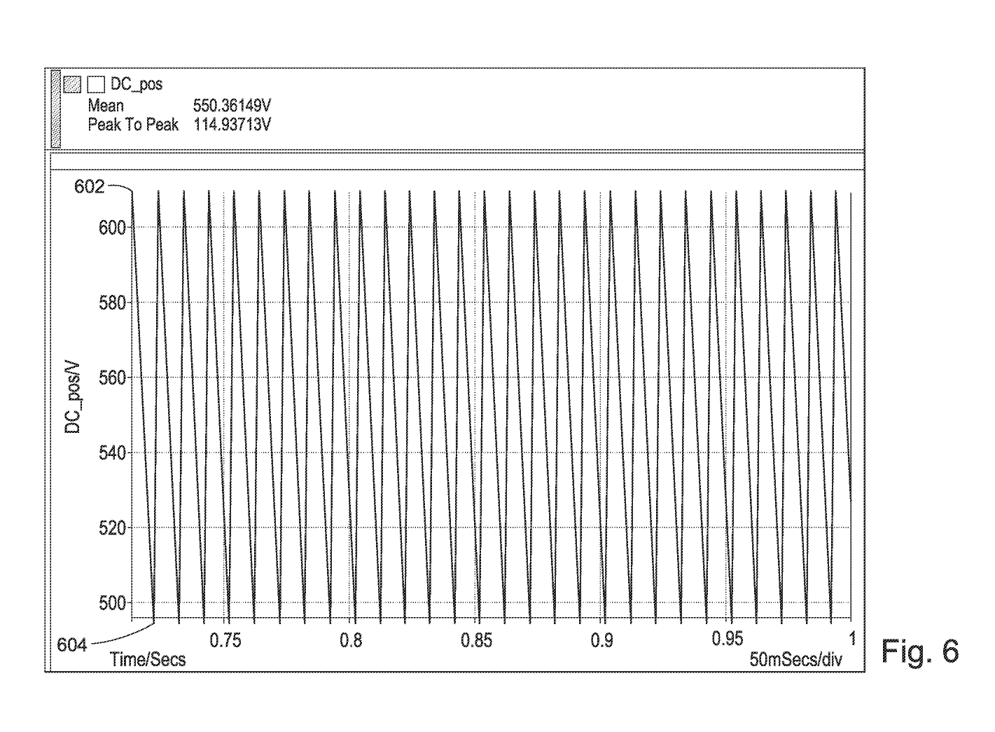

FIG. 6 shows the resultant waveform when one spacer 208 is missing from one of the circuit board to circuit board connections 302, 304 and 306. In this case, the difference between a peak 602 and a trough 604 is larger than the difference between the peak 506 and the trough 508 of FIG. 5, and represents an increase in the ripple voltage. In this example FIG. 6, the ripple voltage is increased to 114V from the 63V shown in FIG. 5. Due to the missing spacer 208, only two phases of the three phase input enter the circuit of FIG. 4, therefore the resultant waveform is that shown in FIG. 6. The microprocessor detects the increased ripple voltage as exceeding the ripple voltage threshold. In the event that a spacer 208 is missed, only two phases of the three phase system are present and the input ripple frequency of the DC bus is reduced. The input ripple frequency may be reduced to 200 Hz, for example. This means that the DC bus capacitors are no longer optimised for the now reduced input ripple frequency of the DC bus, and accordingly an increased ripple voltage is present, as shown in FIG. 6 for example. The increased ripple voltage can be detected by the microprocessor as a voltage exceeding the ripple voltage threshold.

In the event that the microprocessor detects a ripple voltage exceeding the ripple voltage threshold on the DC bus 308, and therefore indicative of at least one spacer 208 missing, the electrical device is reported as faulty. Accordingly, faulty systems are not shipped out to customers and may be rendered fully functional. This means that failure in the assembly of systems due to the absence of one or more spacers 208 can be detected very early on in the process and only correctly assembled systems will be sent to end users. This provides increased safety and accordingly a more reliable system is provided.

The detection is not limited to a three phase power supply, and indeed any number of phases can be used. The algorithm of the microprocessor software is configured to a predetermined ripple voltage threshold associated with the number of phases of the power supply. In the event that one or more phases are not present, the ripple voltage exceeds the predetermined ripple voltage threshold, which is considered to be indicative of a missing spacer, and the electrical device is reported as faulty.

Alternatively, the detection of the ripple voltage threshold being exceeded need not be performed by a microprocessor. An analogue circuit comprising a DC filter and a comparator can be used to detect the increase in ripple voltage. As would be understood by the person skilled in the art, an example comparator has an inverting input and a non-inverting input, and may be arranged to compare the ripple voltage on the DC bus with the predetermined ripple voltage threshold. By measuring the output of the comparator using any suitable means, the electrical device can be detected as faulty if a corresponding voltage considered to be indicative of a missing spacer is measured at the comparator output.

A fixing means other than a screw may be used. Any fixing means that exerts pressure on the circuit boards such that the spacer 208 is in physical contact with both the first circuit board 202 and the second circuit board 204 can be used. For example, a metal nut and bolt or rivet may be used in place of the insert 226 and screw 206 respectively, and a plastic nut may be used in place of a plastic insert. As another example, a C-shaped spring clamp 702 or a bow spring clamp 704 may also be used, as shown for example in FIG. 7. Both the C-shaped spring clamp 702 and the bow spring clamp 704 contact both a top side 706 of the first circuit board 202 and a bottom side 708 of the second circuit board 204. In these embodiments, the spacer 208 is held in physical contact with conductive pads on both the first circuit board 202 and the second circuit board 204 by the pressure exerted by the C-shaped spring clamp 702 or the bow spring clamp 704. There may also be conductive pads on the top side 706 of the first circuit board 202 and the bottom side 708 of the second circuit board 204, and the C-shaped spring clamp 702 or the bow spring clamp 704 may physically contact these conductive pads. In this case, if the C-shaped spring clamp 702 or the bow spring clamp 708 is made of metal, isolation means 222 is provided between the conductive pads on one or both of the top side 706 of the first circuit board 202 and the bottom side 708 of the second circuit board 204 and the metal body of the C-shaped spring clamp 702 or the bow spring clamp 704. In this way electrical isolation between the C-shaped spring clamp 702 or the bow spring clamp 704 and the circuit boards is achieved. Although both a C-shaped spring clamp 702 and a bow spring clamp 704 are shown in FIG. 7, only a single type of clamp may be used, as would be understood by the person skilled in the art. Furthermore, although two clamps 702 and 704 are illustrated, any number of clamps may be used, including only one clamp.

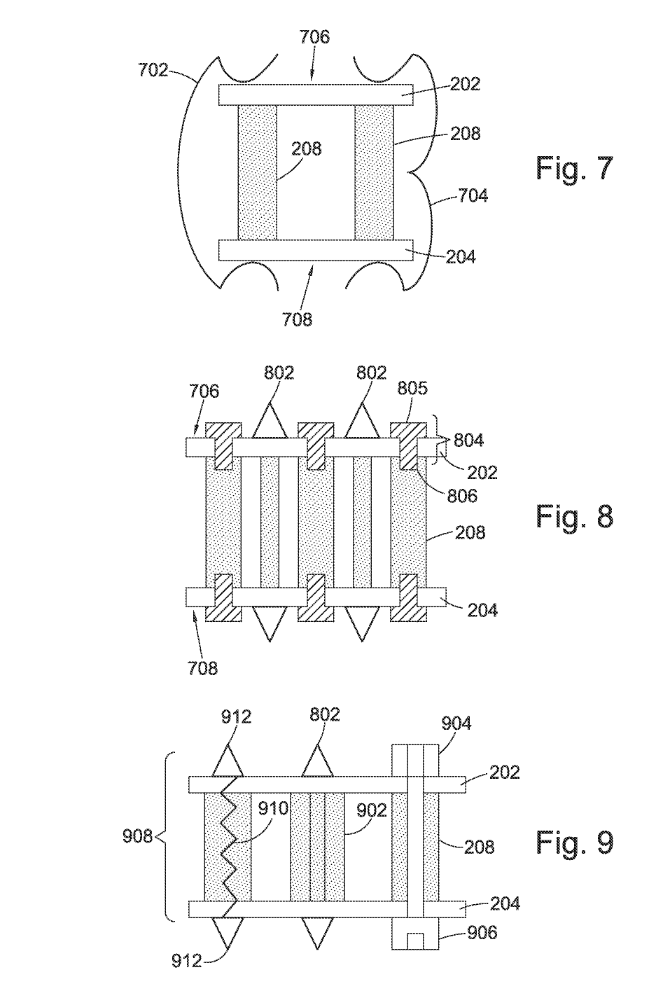

In an alternative embodiment shown in FIG. 8, one or more plastic PCB holders 802 and one or more plugs 804 can be used as an alternative to the screw fixing means. Each plastic PCB holder could be arranged in a similar manner to the screw to provide a mechanical connection between the first circuit board 202 and the second circuit board 204. Specifically, each plastic PCB holder can be inserted into the standard holes in a circuit board to mechanically fix the circuit board to the plastic PCB holder, as would be understood by the person skilled in the art. In this embodiment, the plastic PCB holders 802 are positioned between the first circuit board 202 and the second circuit board 204, and inserted into aligning holes in the first and second circuit boards to mechanically fix the first circuit board 202 to the second circuit board 204, as shown in FIG. 8.

In the embodiment of FIG. 8, one or more spacers 208 are aligned with conductive pads on both the first circuit board 202 and the second circuit board 204. The length of the spacers 208 is such that the spacers 208 physically contact conductive pads on both the first circuit board 202 and the second circuit board 204 when the PCB holders 802 are present. Therefore an electrically conductive path is created between the first circuit board 202, the spacers 208 and the second circuit board 204. Each spacer 208 also engages with two plugs 804. The plugs 804 comprise a head 805 and a cylindrical body 806, the cylindrical body 806 being shaped such that it can be inserted through holes 214 and 216 to enable the body 806 to protrude into the region between the first circuit board 202 and the second circuit board 204. Since the cylindrical body 806 of each plug protrudes through the circuit boards, the cylindrical body 806 is able engage with the spacer 208 to prevent lateral movement of the spacer 208. When inserted into holes 214 and 216, the heads 805 of plugs 804 are arranged to be in contact with the top surface 706 of the first circuit board 202 and the bottom surface 708 of the second circuit board 204. Accordingly the combination of the plastic PCB holders 802 and the plugs 804 secure the spacer 208 in contact with conductive pads on the first and second circuit boards to form an electrically conductive path between the first circuit board 202 and the second circuit board 204.

The plugs 804 may be made of an insulating material, for example plastic, but may also be made of an electrically conductive material, for example brass as any one plug does not span the gap between two corresponding circuit boards. The plastic PCB holders 802 do not require the use of isolation means 222 since they are electrical insulators. Further, in this embodiment there may be no need for the insert 226 and accordingly the resultant apparatus is simpler.

In an alternative embodiment shown in FIG. 9, the spacer 208 may be configured to allow insertion of the plastic PCB holder 802 therethrough. This may be achieved by having a spacer 902 of appropriate central hole diameter. In this embodiment, the spacer 902 is held in physical contact with conductive pads on both the first circuit board 202 and the second circuit board 204 by the plastic PCB holder 802. Since the plastic PCB holder 802 is made of an electrically insulating material, the plastic PCB holder 802 is electrically isolated from the first circuit board 202 and the second circuit board 204 at all times. Therefore the isolation means 222 is not required, and only the spacer 208 is able to create an electrically conductive path between the first circuit board 202 and the second circuit board 204.

Alternatively, as also shown in FIG. 9 a plastic nut 904 and plastic bolt 906 may be used instead of the screw 206. In this embodiment, as the nut 904 and bolt 906 are made of an electrically insulating material, they are electrically isolated from the first circuit board 202 and the second circuit board 204. Accordingly, no isolation means 222 is required, and an electrically conductive path between the first board 202 and the second board 204 is only achieved when the spacer 208 is present.

Alternatively, as also shown in FIG. 9, a spring mechanism 908 may be used instead of the screw 206. In this embodiment, the body 910 of the spring mechanism 908 is substantially spring-like and is shaped to be inserted through first circuit board 202, the spacer 208 or 902, and the second circuit board 204. Anchoring points 912 are located at each end of the body 910, and are shaped such that when the body 910 is inserted through the first circuit board 202, the spacer 208 or 902, and the second circuit board 204, the first circuit board 202 is mechanically coupled to the second circuit board 204. Due to the nature of the spring mechanism 908, the spacer 208 or 902 is held in physical contact with conductive pads on both the first circuit board 202 and the second circuit board 204 by the tension in the spring body 910, and therefore an electrically conductive path between the first circuit board 202, the spacer 208 or 902, and the second circuit board 204 is provided.

The spring mechanism 908 may be made of an electrically insulating material, such as plastic, or an electrically conductive material, such as metal. In the case where the spring mechanism 908 is made of metal, isolation between one of the first circuit board 202 or second circuit board 204 may be required (as described previously in relation to the screw 206). This may take the form of isolation means 222, positioned between one or both anchoring points 912 and conductive pads on the first circuit board 202 and/or the second circuit board 204.

As long as at least one of the first circuit board 202 or the second circuit board 204 is electrically isolated from the fixing means 206, the above described advantages of increased safety and reduced electrical resistance are achieved, and the undesired effects of overheating of the fixing means and potential arcing of current are avoided. Furthermore, failure in the assembly of systems due to the absence of one or more spacers 208 can be detected easily very early on in the process, and only correctly assembled systems will be sent to end users. This provides increased safety and accordingly a more reliable system.

1. An apparatus for connecting two or more circuit boards, the apparatus comprising:
a first circuit board comprising a first surface and a second surface, the second surface having a first conductive pad;
a second circuit board comprising a third surface and a fourth surface, the third surface having a second conductive pad;
a fixing means configured to engage with the first circuit board and the second circuit board to couple the first circuit board to the second circuit board, wherein, when coupled, the fixing means is electrically isolated from one of the first circuit board and the second circuit board; and
an electrically conductive spacer configured to electrically couple the first conductive pad and the second conductive pad.

2. The apparatus of claim 1 wherein the first circuit board comprises a first hole extending between the first surface and the second surface, and the second circuit board comprises a second hole extending between the third surface and the fourth surface, and optionally wherein the first conductive pad is located proximate to the first hole and the second conductive pad is located proximate to the second hole, and further optionally wherein the fixing means is configured to engage with the first hole and the second hole, and further optionally wherein the electrically conductive spacer is configured to allow insertion of the fixing means therethrough.

3. The apparatus of claim 1 wherein at least one of the first circuit board and the second circuit board comprises a printed circuit board (PCB).

4. The apparatus of claim 1 wherein the fixing means is electrically isolated from the electrically conductive spacer.

5. The apparatus of claim 1 wherein the electrically conductive spacer is substantially cylindrical in shape.

6. The apparatus of claim 2 wherein the first surface comprises a third conductive pad located proximate to the first hole, and the first surface further comprises an isolation means located to electrically isolate the third conductive pad from the fixing means.

7. The apparatus of claim 1 wherein the fixing means is a screw with a screw head.

8. The apparatus of claim 6 wherein the fixing means is a screw with a screw head and the isolation means is located between the head of the screw and the third conductive pad.

9. The apparatus of claim 2 wherein at least one of the first or second fixing holes is electrically isolated from the fixing means.

10. The apparatus of claim 1 wherein the apparatus is arranged to be electrically connected to a detection system.

11. The apparatus of claim 10 wherein the detection system is configured to detect a signal indicative of the presence of the electrically conductive spacer.

12. The apparatus of claim 11 wherein the detection system detects the presence of the electrically conductive spacer by monitoring a ripple voltage.

13. The apparatus of claim 11 wherein an error message is displayed when the electrically conductive spacer is detected as not being present.

14. The apparatus of claim 12 wherein an error message is displayed when the ripple voltage exceeds a predetermined ripple voltage threshold.

15. The apparatus of claim 1 wherein the first and second conductive pads are made of copper.

16. A method for connecting two or more PCBs, the method comprising:
providing a first PCB comprising a first surface and second surface, the second surface having a first conductive pad;
providing a second PCB comprising a third surface and a fourth surface, the third surface having a second conductive pad;
coupling the first circuit board and the second circuit board with a fixing means, the fixing means being electrically isolated from one of the first circuit board and the second circuit board; and
electrically coupling the first conductive pad and the second conductive pad with an electrically conductive spacer.

17. The method of claim 16 further comprising providing a first hole extending between the first surface and the second surface, and providing a second hole extending between the third surface and the fourth surface, and optionally wherein the first conductive pad is located proximate to the first hole and the second conductive pad is located proximate to the second hole, and further optionally wherein the fixing means is configured to engage with the first hole and the second hole, and further optionally
wherein the electrically conductive spacer is configured to allow insertion of the fixing means therethrough.

18. The method of claim 16 further comprising providing a detection system configured to detect a signal indicative of the presence of the electrically conductive spacer and optionally further comprising detecting the presence of the electrically conductive spacer by monitoring ripple voltage.

19. The method of claim 18 further comprising displaying an error message when the electrically conductive spacer is detected as not being present.

20. The method of claim 19 further comprising displaying an error message when the ripple voltage exceeds a predetermined voltage threshold.
